(19) United States
(12) Patent Application Publication
(10) Pub. No.: US 2009/0251183 A1
(43) Pub. Date: Oct. 8, 2009

(54) DELAY LOCK LOOP CIRCUIT AND SEMICONDUCTOR DEVICE

(75) Inventor: Junichi HAYASHI, Chuo-ku (JP)

Correspondence Address: SUGHRUE MION, PLLC, 2100 PENNSYLVANIA AVENUE, N.W., SUITE 800, WASHINGTON, DC, 20037, US

(73) Assignee: ELPIDA MEMORY, INC., Tokyo (JP)

(21) Appl. No.: 12/416,504

(22) Filed: Apr. 1, 2009

(30) Foreign Application Priority Data
Apr. 8, 2008 (JP) 2008-100577

(51) Int. Cl. H03L 7/06

(52) U.S. Cl. 327/158

(57) ABSTRACT

A simple circuit for preventing occurrence of a hazard and output delay for an asynchronous input signal in a clock signal. A flip-flop circuit (FF) outputs an output signal at a low level to a clocked inverter circuit (INVO) when a clock signal (PCLKB) transitions from a high level to a low level after an enabling signal (ENAT) goes to a high level. The clocked inverter circuit (INVO) is active when the clock signal (PCLKB) is at a low level, and inverts an output signal of the flip-flop circuit (FF) and outputs the output signal to a holding circuit (LATCH). The holding circuit (LATCH) holds the output signal of the clocked inverter circuit (INVO) and outputs the output signal as a signal (ENAOUT).

### TECHNICAL FIELD

### Reference to Related Application

The present invention is based upon and claims the benefit of the priority of Japanese Patent Application No. 2008-100577 filed on Apr. 8, 2008, the disclosure of which is incorporated herein in its entirety by reference thereto.

The present invention relates to a delay lock loop circuit and semiconductor device, and in particular, to a preferred output control circuit in a semiconductor memory device or the like, for controlling output timing of the delay lock loop circuit.

### BACKGROUND

Among SDRAMs (Synchronous Dynamic Random Access Memory), in particular with DDR (Double Data Rate) SDRAMs, DLL circuits are used in output timing control in order to match an output operation with an external clock signal. These DLL circuits are configured such that a delay of an internal clock signal is adjusted to match output timing with the external clock signal, but a clock signal is not always continually outputted. In many cases, output control is enabled by a read command or the like, and output operation is started. However, in order to match the output operation with the external clock signal, a DLL circuit itself often continues to operate for comparison operations or the like, and there are cases in which the output operation only is stopped, to perform control. In order to create an enabling signal for this output control, an output control circuit having an internal clock signal and a control signal as input signals is used.

An example of this type of output control circuit is disclosed in Patent Document 1. This circuit is provided with a circuit for latching a mask signal received from outside, with a first internal clock signal and a circuit for latching with a second internal clock signal; the circuit is further provided with a circuit for generating a second pre-output enabling signal by a logical operation on the latched mask signal and an internal pre-output enabling signal, and is provided with an output enabling signal generation circuit which receives the second pre-output enabling signal. According to this type of circuit, an output enabling signal hazard is prevented, and higher speed access is realized by eliminating delay in the output enabling signal generation due to delay of an output data mask signal path.

### [Patent Document 1]

JP Patent Kokai Publication No. JP-A-07-85663

### SUMMARY

The entire disclosure of above Patent Document is incorporated herein by reference thereto.

The following analysis is given by the present invention.

In the circuit described in Patent Document 1, however, since a constant timing setting is required in a control signal, it is not possible to handle a completely asynchronous signal. That is, since a hazard occurs when a mask signal arrives after a reset signal, a method is taken in which timing is determined so that the mask signal arrives before the reset signal. For this reason, a data latch circuit is used, but an internal clock signal for latch control is necessary, and a need arises for control somewhere of timing thereof. Accordingly, for asynchronous operation, a complex circuit configuration results, in order to prevent occurrence of a hazard and output delay. Thus there is much to be desired in the art.

It is an object of the present invention to provide an output control circuit of a simple circuit configuration for preventing occurrence of a hazard and output delay for an asynchronous input signal in a clock signal.

According to a first aspect of the present invention, there is provided a delay lock loop circuit comprising: a delay lock loop, and an output control circuit which output controls output of an output signal of the delay lock loop. The output control circuit is provided with a flip-flop circuit which performs set-reset operation by an enabling signal that output controls output of a clock signal received by the delay lock loop, and the output signal; a clock driver logic circuit which outputs an output signal of the flip-flop circuit when the clock signal goes to a first logic level; and a holding circuit which holds the output signal of the clock driver logic circuit. Output control of the output signal of the delay lock loop is performed by an output signal of the holding circuit.

According to a second aspect of the present invention, there is provided a semiconductor device comprising: an output circuit of a semiconductor device; and a delay lock loop circuit which generates an output signal that controls output timing of the output circuit. The delay lock loop circuit is provided with a delay lock loop; and an output control circuit which output controls output of an output signal of the delay lock loop. The output control circuit is provided with a flip-flop circuit which performs set-reset operation by an enabling signal that output controls output of a clock signal received by the delay lock loop, and the output signal; a clock driver logic circuit which outputs an output signal of the flip-flop circuit when the clock signal goes to a first logic level; and a holding circuit which holds the output signal of the clock driver logic circuit. Output control of the output signal of the delay lock loop is performed by an output signal of the holding circuit.

In the output control circuit of the present invention, it is preferable that the flip-flop circuit puts an output signal to an active level when, after the enabling signal has an active level, the clock signal transitions from a second logic level to a first logic level; and the clock driver logic circuit is a clocked inverter circuit which is made active when the clock signal is at a first logic level, and which inverts and outputs an output signal of the flip-flop circuit.

The DLL circuit of the present invention may be provided with the abovementioned output control circuit, and generation of an internal clock signal by output of the holding circuit may be controlled.

A semiconductor memory device of the present invention may be provided with the abovementioned DLL circuit, and may control output timing of an output signal based on an internal clock signal generated by the DLL circuit.

The meritorious effects of the present invention are summarized as follows.

According to the present invention, it is possible to realize a simple circuit configuration in which, for an internal clock signal, a hazard is not caused even if a control signal is asynchronously received, and an enabling signal is outputted with no wasteful delay from the internal clock signal.

### BRIEF DESCRIPTIONS OF THE DRAWINGS

FIG. 1 is a circuit diagram of an output control circuit according to a first exemplary embodiment of the present invention.

FIG. 2A-2C are timing charts representing operation of the output control circuit according to the first exemplary embodiment of the invention.

FIG. 3 is a drawing showing a configuration of a DLL circuit according to a second exemplary embodiment of the present invention.

### PREFERRED MODES OF THE INVENTION

Various modes are embraced in the present invention. The first aspect aforementioned represents a first mode, whereas the second aspect aforementioned represents a second mode.

In the delay lock loop (DLL) circuit according to the first and second mode, the flip-flop circuit may put an output signal to an active level when, after the enabling signal has an active level, the clock signal transitions from a second logic level to a first logic level; and the clock driver logic circuit may be a clocked inverter circuit which is made active when the clock signal is at a first logic level, and which inverts and outputs an output signal of the flip-flop circuit.

In the delay lock loop circuit, the clock signal may be a synchronous signal of a prescribed period, and the enabling signal may be a signal that is asynchronous with the synchronous signal.

In the delay lock loop circuit, the delay lock loop may comprise: a phase comparator circuit which receives a synchronous signal of a prescribed period and compares phase of the synchronous signal; and a delay adjustment circuit which adjusts delay of the clock signal from a comparison result of the phase comparator circuit; and wherein the phase comparator circuit and the delay adjustment circuit may operate constantly except in a power down mode, and an output operation of the output signal of the delay lock loop may be controlled according to the enabling signal.

In the delay lock loop circuit or the semiconductor device, output timing of an output signal of an output circuit of a semiconductor device may be controlled based on an output signal of the delay lock loop.

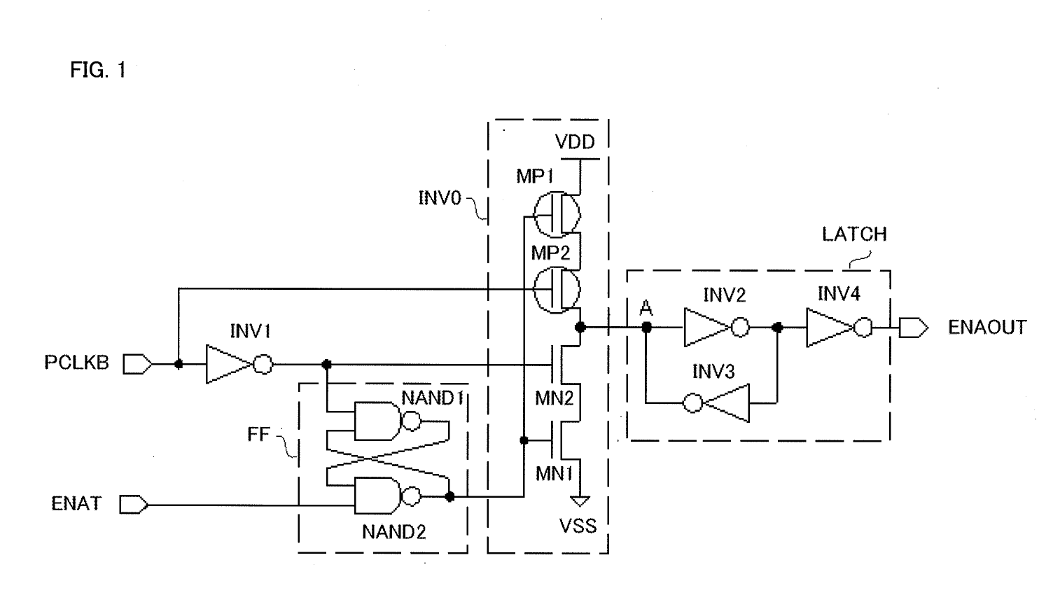

An output control circuit according to an exemplary embodiment of the present invention is provided with a flip-flop circuit (FF in FIG. 1) which outputs an output signal at a low level to a clocked inverter circuit (INVO in FIG. 1) when a clock signal (PCLKB in FIG. 1) transitions from a high level to a low level after an enabling signal (ENAT in FIG. 1) goes to a high level; the clocked inverter circuit (INVO in FIG. 1) which is active when the clock signal (PCLKB in FIG. 1) is at a low level, and which inverts an output signal of the flip-flop circuit (FF in FIG. 1) and outputs to a holding circuit (LATCH in FIG. 1); and the holding circuit (LATCH in FIG. 1) which holds the output signal of the clocked inverter circuit (INVO in FIG. 1) and outputs the output signal as a signal (ENAOUT in FIG. 1).

According to this type of output control circuit, by combining the flip-flop circuit with the clocked inverter circuit, it is possible to control output timing by an internal clock signal even if an enabling signal is received asynchronously with the internal clock signal, and it is possible to suppress generation of a hazard. Since a hazard is not generated, there is no need to use a wasteful delay element for elimination thereof, and therefore it is possible to output the enabling signal with no wasteful delay from the internal clock signal.

A detailed description is given below, making reference to the drawings, according to exemplary embodiments.

### First Exemplary Embodiment

FIG. 1 is a circuit diagram of an output control circuit according to a first exemplary embodiment of the present invention. In FIG. 1, the output control circuit is provided with an inverter circuit INV1, a clocked inverter circuit INVO, a flip-flop circuit FF, and a latch circuit LATCH. The clocked inverter circuit INVO is provided with Pch transistors MP1 and MP2, Nch transistors MN2 and MN1, in a cascade arrangement across power supplies VDD and VSS. The flip-flop circuit FF is an RS flip-flop circuit, and is provided with 2 input NAND circuits NAND1 and NAND2 in which one input terminal and an output terminal are connected crossing-wise to one another. The latch circuit LATCH is provided with inverter circuits INV2 and INV3 in which input and output are connected to each other, and an inverter circuit INV4 which inverts output of the inverter circuit INV2 and provides output as an enabling signal ENAOUT.

The internal clock signal PCLKB is supplied to a gate of the Pch transistor MP2, and is supplied to a gate of the Nch transistor MN2 via the inverter circuit INV1 and to the other input terminal of the NAND circuit NAND1. The control signal ENAT is supplied to the other input terminal of the NAND circuit NAND2. The output terminal of the NAND circuit NAND2 is connected to gates of the Pch transistor MP1 and the Nch transistor MN1. Output of the clocked inverter circuit INVO, that is, drains of the Pch transistor MP2 and the Nch transistor MN2, at a node A, is connected to input of the inverter circuit INV2 and to output of the inverter circuit INV3.

The output control circuit has the internal clock signal PCLKB and the control signal ENAT as input signals, and with regard to each thereof, after controlling an enabling state by the flip-flop circuit FF, outputs to the clocked inverter circuit INVO. In order that the output timing of the output control circuit corresponds to timing of the internal clock signal PCLKB, the internal clock signal PCLKB and an inverted signal of the internal clock signal PCLKB are given to the clocked inverter circuit INVO. In addition, an output signal of the clocked inverter circuit INVO is latched by the latch circuit LATCH at the node A.

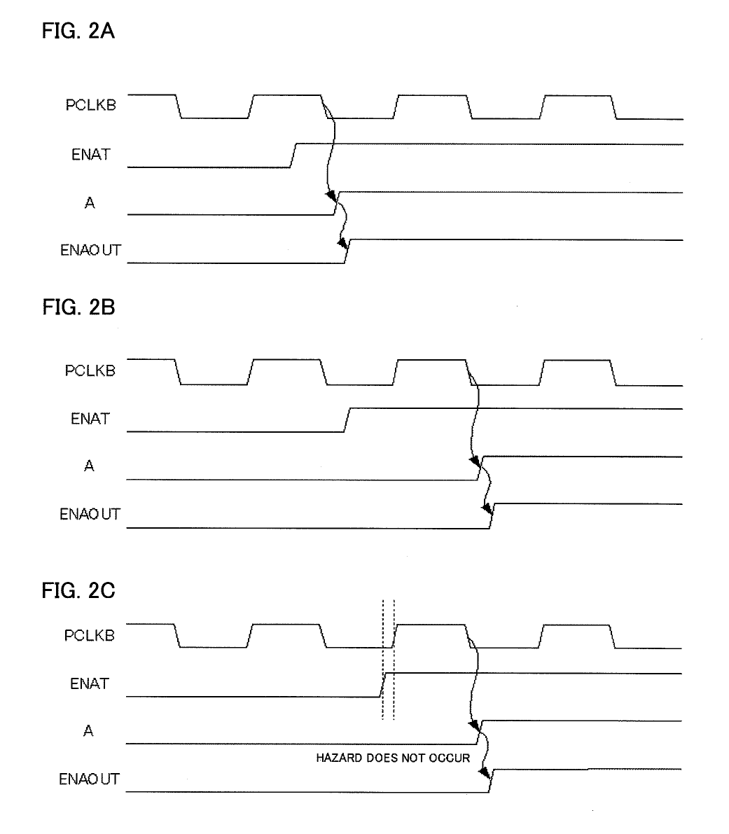

Next, a description is given concerning operation of the output control circuit of FIG. 1 using a time chart of FIGS. 2A-2C. The internal clock signal PCLKB is a clock signal that clocks at a fixed cycle, and when the control signal ENAT goes from a low level to a high level, the output control circuit becomes enabled. In general, in a state in which the control circuit is enabled, when the internal clock signal PCLKB goes to a high level, the output enabling signal ENAOUT goes from a low level to a high level. However, in the present invention, occurrence of such transition is suppressed as explained below.

FIG. 2A illustrates a case in which the control signal ENAT goes to a high level during a period in which the internal clock signal PCLKB has a high level. By the control signal ENAT having a high level, the control signal goes into an enabled state by the flip-flop circuit FF, and at a falling edge of the internal clock signal PCLKB, the output enabling signal ENAOUT goes from a low level to a high level. For example, in cases in which the enabling signal ENAOUT is used in output control of the DLL circuit, by the enabling signal ENAOUT having a high level, it is possible to make clock output of the DLL circuit enabled.

FIG. 2B illustrates a case in which the control signal ENAT goes to a high level during a period in which the internal clock signal PCLKB has a low level. Even if the control signal ENAT has a high level, the control signal maintains a disabled state, by the flip-flop circuit FF. When the internal clock signal PCLKB goes to a high level, the control signal has an enabled state by the flip-flop circuit FF, and at a falling edge of the internal clock signal PCLKB, the output enabling signal ENAOUT goes from a low level to a high level.

FIG. 2C illustrates a case in which the control signal ENAT goes to a high level just before the internal clock signal PCLKB goes from a low level to a high level. In such case, since output of the clocked inverter circuit INVO is stopped first upon transition of the internal clock signal PCLKB to a high level, operation is similar to FIG. 2B, without a hazard mistakenly occurring.

According to the output control circuit that operates as above, with regard to the internal clock signal PCLKB, even if the control signal ENAT is asynchronously received, a hazard does not occur in output. Therefore, there is no need to use a redundant delay circuit for eliminating the hazard, and a delay does not occur in the output. The reason for this is that by using the flip-flop circuit FF in the input control, it is possible to control a relationship of the internal clock signal and the control signal that was received asynchronously.

In addition, it is possible to constantly control the output timing of the output enabling signal by the internal clock signal PCLKB. The reason for this is that, in the same way, by using the flip-flop circuit FF in the input control, it is possible to control a relationship of the internal clock signal and the control signal that is received asynchronously, so that it is possible to constantly take timing at a falling edge of the internal clock signal PCLKB.

### Second Exemplary Embodiment

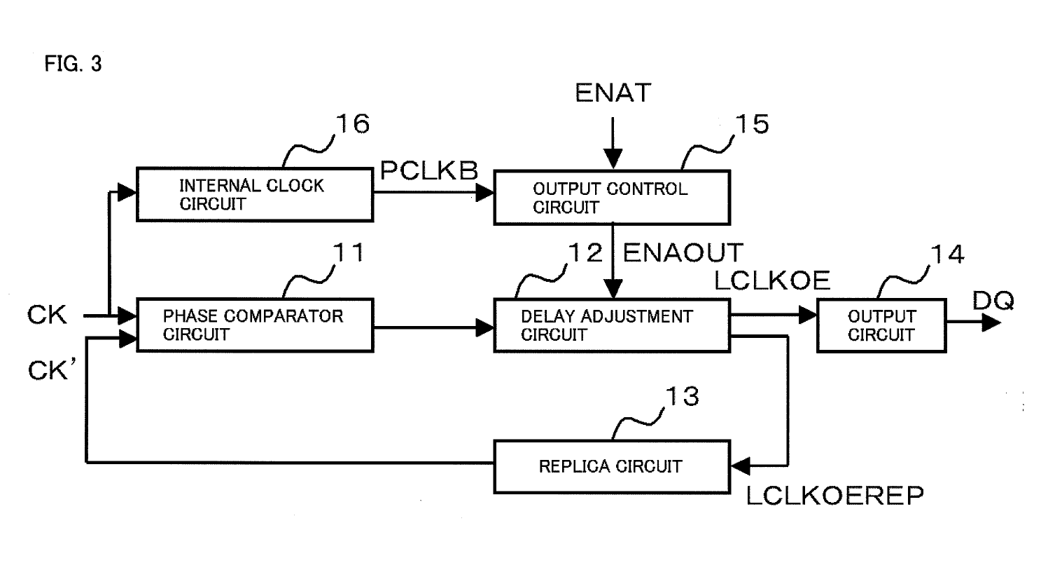

FIG. 3 is a drawing showing a configuration of a DLL circuit according to a second exemplary embodiment of the present invention. In FIG. 3, the DLL circuit is provided with a phase comparator circuit 11, a delay adjustment circuit 12, a replica circuit 13, an output circuit 14, an output control circuit 15, and an internal clock circuit 16, and is used in timing control of a DRAM (Dynamic Random Access Memory) or the like, for example.

The phase comparator circuit 11 compares an external clock signal CK and an internal clock signal CK′. The delay adjustment circuit 12, from a result of comparison in the phase comparator circuit 11, performs delay adjustment such as advancing or retarding a delay of the external clock signal CK, and outputs internal clock signals LCLKOE and LCLKOEREP. The replica circuit 13 is a circuit that shows a replica of input or output, and with regard to the internal clock signal LCLKOEREP, outputs the internal clock signal CK′ that was adjusted by the replica, to the phase comparator circuit 11. The output circuit 14 outputs data output DQ for which output timing is adjusted by the internal clock signal LCLKOE.

Excepting cases in which operation is stopped in a power down mode or the like, the phase comparator circuit 11 constantly compares phase at a fixed cycle, and continues to forward comparison results to the delay adjustment circuit 12. The delay adjustment circuit 12 performs adjustment of the number of delay stages used etc., according to the comparison result, but there is no need to constantly output the internal clock signal LCLKOE. Since the internal clock signal LCLKOE is used for outputting DQ, LCLKOE may be outputted only when DRAM is read, and except for this period, output is stopped in order to reduce current. For example, by controlling output by a read command, it is possible to reduce operation current outside of reading. The delay adjustment circuit 12 continues to forward the internal clock signal LCLKOEREP to the replica circuit 13, except in cases in which operation is stopped in a power down mode or the like.

An output control circuit 15 is the output control circuit as described in the first exemplary embodiment, and is a circuit that controls output of the internal clock signal LCLKOE for the delay adjustment circuit 12. The output control circuit 15 uses an internal clock signal PCLKB and an enabling signal ENAT created by a read command, for example, and creates an enabling signal ENAOUT for controlling output of the internal clock signal LCLKOE for the delay adjustment circuit 12. Here, the internal clock signal PCLKB is a clock signal for internal control, not an internal clock signal adjusted by the DLL circuit, and is directly created from the external clock signal CK by the internal clock circuit 16. That is, the internal clock circuit 16, after converting the external clock signal CK that has a small amplitude to a desired amplitude by an input initial stage circuit, which is not illustrated in the drawings, creates the internal clock signal PCLKB of one shot width for internal control. This internal clock signal PCLKB of one shot width is used for latch control of an address command of a DRAM, clock control, and the like.

If the output control circuit according to the first exemplary embodiment is used as the output control circuit 15, transmission at high speed is performed from the control signal to output enabling. Therefore, even if the operation speed (operation frequency) becomes faster, it is possible to make a mismatch of timing (clock mismatch), at which the internal clock signal LCLKOE is enabled in the delay adjustment circuit 12, more difficult to occur.

Each patent document disclosure described above is incorporated into the present specification by reference thereto. Modifications and adjustments of embodiments and examples are possible within bounds of the entire disclosure (including the claims) of the present invention, and also based on fundamental technological concepts thereof. Furthermore, a wide variety combinations and selections of various disclosed elements are possible within the scope of the claims of the present invention. That is, the present invention clearly includes all types of modification and alteration that could be realized by a person skilled in the art, according to technological concepts and the entire disclosure including the scope of the claims.

According to a technological concept of the present invention, there is no limitation to applications to a DRAM, and, for example, the invention may be used in synchronous memory devices and synchronous semiconductor devices, without limitation to memory. Furthermore, according to a technological concept of the present invention, there is no limitation to a DLL circuit, and the invention may be used in a PLL (Phased Lock Loop) circuit, for example. In addition, in the present exemplary embodiments, polarity of each MOS transistor was configured as described above, but the circuits can be configured with all the polarity of these MOS transistors reversed. In such cases, relationships and the like of power supply potential and ground, and polarity of control signals, are reversed. Furthermore, the transistors may be Field Effect Transistors (FETs), and application is possible to various FETs such as a MIS (Metal-Insulator Semiconductor) transistor, other than MOS (Metal Oxide Semiconductor). Moreover, the transistors may also be bipolar transistors.

It should be noted that other objects, features and aspects of the present invention will become apparent in the entire disclosure and that modifications may be done without departing the gist and scope of the present invention as disclosed herein and claimed as appended herewith.

Also it should be noted that any combination of the disclosed and/or claimed elements, matters and/or items may fall under the modifications aforementioned.

What is claimed is:

1. A delay lock loop circuit comprising:
a delay lock loop; and
an output control circuit which output controls output of an output signal of said delay lock loop; wherein
said output control circuit comprises:
a flip-flop circuit which performs set-reset operation by an enabling signal that output controls output of a clock signal received by said delay lock loop, and said output signal;
a clock driver logic circuit which outputs an output signal of said flip-flop circuit when said clock signal goes to a first logic level; and
a holding circuit which holds the output signal of said clock driver logic circuit; and wherein
output control of the output signal of said delay lock loop is performed by an output signal of said holding circuit.

2. The delay lock loop circuit according to claim 1, wherein
said flip-flop circuit puts an output signal to an active level when, after said enabling signal has an active level, said clock signal transitions from a second logic level to a first logic level; and
said clock driver logic circuit is a clocked inverter circuit which is made active when said clock signal is at a first logic level, and which inverts and outputs an output signal of said flip-flop circuit.

3. The delay lock loop circuit according to claim 1, wherein said clock signal is a synchronous signal of a prescribed period, and said enabling signal is a signal that is asynchronous with said synchronous signal.

4. The delay lock loop circuit according to claim 1, wherein
said delay lock loop comprises:
a phase comparator circuit which receives a synchronous signal of a prescribed period and compares phase of said synchronous signal; and
a delay adjustment circuit which adjusts delay of said clock signal from a comparison result of said phase comparator circuit; and wherein
said phase comparator circuit and said delay adjustment circuit operate constantly except in a power down mode, and
an output operation of the output signal of said delay lock loop is controlled according to said enabling signal.

5. The delay lock loop circuit according to claim 1, wherein output timing of an output signal of an output circuit of a semiconductor device is controlled based on an output signal of said delay lock loop.

6. A semiconductor device comprising:
an output circuit of said semiconductor device; and
a delay lock loop circuit which generates an output signal that controls output timing of said output circuit; wherein
said delay lock loop circuit comprises:
a delay lock loop; and
an output control circuit which output controls output of an output signal of said delay lock loop;
said output control circuit comprises:
a flip-flop circuit which performs set-reset operation by an enabling signal that output controls output of a clock signal received by said delay lock loop, and said output signal;
a clock driver logic circuit which outputs an output signal of said flip-flop circuit when said clock signal goes to a first logic level; and
a holding circuit which holds the output signal of said clock driver logic circuit; and wherein
output control of the output signal of said delay lock loop is performed by an output signal of said holding circuit.

7. The semiconductor device according to claim 6, wherein
said flip-flop circuit puts an output signal to an active level when, after said enabling signal has an active level, said clock signal transitions from a second logic level to a first logic level; and
said clock driver logic circuit is a clocked inverter circuit which is made active when said clock signal is at a first logic level, and which inverts and outputs an output signal of said flip-flop circuit.

8. The semiconductor device according to claim 6, wherein said clock signal is a synchronous signal of a prescribed period, and said enabling signal is a signal that is asynchronous with said synchronous signal.

9. The semiconductor device according to claim 6, wherein
said delay lock loop comprises:
a phase comparator circuit which receives a synchronous signal of a prescribed period and compares phase of said synchronous signal; and
a delay adjustment circuit which adjusts delay of said clock signal from a comparison result of said phase comparator circuit; and wherein
said phase comparator circuit and said delay adjustment circuit operate constantly except in a power down mode, and
an output operation of the output signal of said delay lock loop is controlled according to said enabling signal.

10. The semiconductor device according to claim 6, wherein output timing of an output signal of an output circuit of said semiconductor device is controlled based on an output signal of said delay lock loop.
